(19) United States
(12) Patent Application Publication
(10) Pub. No.: US 2022/0274884 A1
(43) Pub. Date: Sep. 1, 2022

(54) COMPACT OF POWDER AND FILLER POWDER

(71) Applicant: Sumitomo Chemical Company, Limited, Chuo-ku, Tokyo (JP)

(72) Inventors: Atsunori DOI, Tsukuba-shi (JP); Satoshi SHIMANO, Tsukuba-shi, Ibaraki (JP)

(21) Appl. No.: 17/625,116

(22) PCT Filed: Jun. 22, 2020
(86) PCT No.: PCT/JP2020/024354

§ 371 Date: Jan. 6, 2022

(30) Foreign Application Priority Data
Jul. 12, 2019 (JP) 2019-130447

(51) Int. Cl. C04B 35/46

(52) U.S. Cl. CPC C04B 35/46; C04B 2235/78

(57) ABSTRACT

Provided is a compact of a powder satisfying requirements 1 to 3. Requirement 1: |dA(T)/dT| of the powder is 10 ppm/° C. or more at least at −200 to 1,200° C., where A is (a lattice constant of a-axis)/(a lattice constant of c-axis) obtained from X-ray diffractometry. Requirement 2: the powder contains at least one metal or semimetal element, and the element is composed of only an element selected from the group consisting of Li, Na, Mg, Al, Si, K, Ca, Sc, Ti, V, Cr, Mn, Fe, Co, Ni, Cu, Zn, Ga, Ge, Rb, Sr, Y, Zr, Nb, Mo, Tc, Ag, Cd, In, Sn, Sb, Te, Cs, Ba, Hf, Ta, W, Re, Au, Hg, Tl, Ce, Pr, Nd, Pm, Sm, Eu, Gd, Tb, Dy, Ho, Er, Tm, Yb, and Lu. Requirement 3: the linear thermal expansion coefficient at −200 to 1,200° C. of the compact is negative at least at one temperature.

### TECHNICAL FIELD

The present invention relates to a compact of a powder, and a filler powder.

### BACKGROUND ART

For example, Patent Document 1 discloses a technique in which the linear thermal expansion coefficient of a composition containing a resin is reduced and controlled to a desired level by using tungsten zirconium phosphate which is a material exhibiting a negative linear thermal expansion coefficient as an additive.

### PRIOR ART DOCUMENTS

### Patent Documents

Patent Document 1: JP-A-2018-2577

### SUMMARY OF THE INVENTION

### Problems to be Solved by the Invention

However, the negative linear thermal expansion coefficient of the material itself disclosed in Patent Document 1 is about −3 ppm/° C., and even if a member is produced by mixing such a material with another solid, the linear thermal expansion coefficient thereof cannot necessarily be sufficiently reduced.

The present invention has been made in view of the above circumstances, and an object of the present invention is to provide a compact having a sufficiently low linear thermal expansion coefficient and a filler powder capable of lowering the linear thermal expansion coefficient of a solid composition.

### Means for Solving the Problems

As a result of various studies, the present inventors have reached the present invention. That is, the present invention provides the following invention.

The compact of a powder according to the present invention satisfies the following requirements 1 to 3.

Requirement 1: |dA(T)/dT| of the powder satisfies 10 ppm/° C. or more at at least one temperature T1 in a range of −200° C. to 1,200° C.

A is (an a-axis (shorter axis) lattice constant of a crystal in the powder)/(a c-axis (longer axis) lattice constant of a crystal in the powder), and each of the lattice constants is obtained from X-ray diffractometry of the powder.

Requirement 2: the powder contains at least one metal element or semimetal element, and the at least one metal element or semimetal element is composed of only an element selected from the group consisting of Li, Na, Mg, Al, Si, K, Ca, Sc, Ti, V, Cr, Mn, Fe, Co, Ni, Cu, Zn, Ga, Ge, Rb, Sr, Y, Zr, Nb, Mo, Tc, Ag, Cd, In, Sn, Sb, Te, Cs, Ba, Hf, Ta, W, Re, Au, Hg, Tl, Ce, Pr, Nd, Pm, Sm, Eu, Gd, Tb, Dy, Ho, Er, Tm, Yb, and Lu.

Requirement 3: a linear thermal expansion coefficient at −200° C. to 1,200° C. of the compact is negative at at least one temperature.

Here, the powder may be a metal oxide powder.

The metal oxide powder may contain a metal having d electrons.

The metal oxide powder may be a metal oxide powder containing titanium.

The metal oxide powder containing titanium may be a TiOₓ (x=1.30 to 1.66) powder.

The compact of a powder may be a heat dissipation member, a mechanical member, a container, an optical member, a member for electronic devices, or an adhesive.

The filler powder according to the present invention satisfies the following requirements 1, 2, and 4.

Requirement 1: |dA(T)/dT| of the filler powder satisfies 10 ppm/° C. or more at at least one temperature T1 in a range of −200° C. to 1,200° C.

A is (an a-axis (shorter axis) lattice constant of a crystal in the powder)/(a c-axis (longer axis) lattice constant of a crystal in the powder), and each of the lattice constants is obtained from X-ray diffractometry of the powder.

Requirement 2: the filler powder contains at least one metal element or semimetal element, and the at least one metal element or semimetal element is composed of only an element selected from the group consisting of Li, Na, Mg, Al, Si, K, Ca, Sc, Ti, V, Cr, Mn, Fe, Co, Ni, Cu, Zn, Ga, Ge, Rb, Sr, Y, Zr, Nb, Mo, Tc, Ag, Cd, In, Sn, Sb, Te, Cs, Ba, Hf, Ta, W, Re, Au, Hg, Tl, Ce, Pr, Nd, Pm, Sm, Eu, Gd, Tb, Dy, Ho, Er, Tm, Yb, and Lu.

Requirement 4: a linear thermal expansion coefficient at 25 to 320° C. of a solid composition containing 88 parts by weight of the filler powder and 12 parts by weight of sodium silicate is negative at at least one temperature.

The filler powder may be a metal oxide powder.

The metal oxide powder can be a metal oxide powder having d electrons.

The metal oxide powder can be a metal oxide powder containing titanium.

The metal oxide powder containing titanium can be a TiOₓ (x=1.30 to 1.66) powder.

The present specification further discloses the use of the powder satisfying the requirements 1, 2 and 4 as a filler in a solid material.

The present specification further discloses a method for controlling the linear thermal expansion coefficient of a solid material, the method including the step of blending the powder satisfying the requirements 1, 2, and 4 in a solid material.

The present specification discloses a method for producing a solid composition, the method including the steps of: mixing the powder satisfying the requirements 1, 2, and 4 and a raw material (precursor) of a solid material to obtain a mixture; and converting the precursor in the mixture into a solid material.

### Effect of the Invention

According to the present invention, it is possible to provide a compact having a sufficiently low linear thermal expansion coefficient and a filler powder capable of lowering the linear thermal expansion coefficient of a solid composition.

### BRIEF DESCRIPTION OF THE DRAWINGS

FIG. 1 is a graph showing temperature change of the a-axis length/c-axis length of a filler powder of Example 1, that is, A(T).

FIG. 2 is a graph of temperature dependency of dimensional change rate ΔL(T)/L (30° C.) of Example 3.

### MODE FOR CARRYING OUT THE INVENTION

### First Embodiment: Compact of Powder

The compact of a powder according to the present embodiment satisfies the following requirements 1 to 3.

Requirement 1: |dA(T)/dT| of the powder satisfies 10 ppm/° C. or more at at least one temperature T1 in a range of −200° C. to 1,200° C.

A is (an a-axis (shorter axis) lattice constant of a crystal in the powder)/(a c-axis (longer axis) lattice constant of a crystal in the powder), and each of the lattice constants is obtained from X-ray diffractometry of the powder.

Requirement 2: the powder contains at least one metal element or semimetal element, and the at least one metal element or semimetal element is composed of only an element selected from the group consisting of Li, Na, Mg, Al, Si, K, Ca, Sc, Ti, V, Cr, Mn, Fe, Co, Ni, Cu, Zn, Ga, Ge, Rb, Sr, Y, Zr, Nb, Mo, Tc, Ag, Cd, In, Sn, Sb, Te, Cs, Ba, Hf, Ta, W, Re, Au, Hg, Tl, Ce, Pr, Nd, Pm, Sm, Eu, Gd, Tb, Dy, Ho, Er, Tm, Yb, and Lu.

Requirement 3: a linear thermal expansion coefficient at −200° C. to 1,200° C. of the compact is negative at at least one temperature.

First, the requirement 1 will be described in detail.

The lattice constant in the definition of A is specified by powder X-ray diffractometry. As an analysis method, there are a Rietveld method and an analysis by fitting by a least-squares method.

In the present specification, in the crystal structure specified by powder X-ray diffractometry, an axis corresponding to the smallest lattice constant is defined as an a-axis, and an axis corresponding to the largest lattice constant is defined as a c-axis. The length of the a-axis and the length of the c-axis of the crystal lattice are defined as an a-axis length and a c-axis length, respectively.

A(T) is a parameter indicating the magnitude of anisotropy of the length of the crystal axis, and is the function of a temperature T (unit: ° C.). A larger value of A(T) indicates that the a-axis length is larger relative to the c-axis length, and a smaller value of A indicates that the a-axis length is smaller relative to the c-axis length.

Here, |dA(T)/dT| represents the absolute value of dA (T)/dT, and dA(T)/dT represents the differential of A(T) by T (temperature).

Here, in the present specification, |dA(T)/dT| is defined by the following equation.

|dA(T)/dT|=|A(T+50)−A(T)|/50 (D)

As described above, the powder according to the present embodiment needs to satisfy |dA(T)/dT| of 10 ppm/° C. or more at at least one temperature T1 in a range of −200° C. to 1,200° C. Note that |dA(T)/dT| is defined within a range where the powder exists in a solid state.

Therefore, the maximum temperature of T in the equation (D) is up to a temperature 50° C. lower than the melting point of the powder. That is, when the limitation “at least one temperature T1 in a range of −200° C. to 1,200° C.” is added, the temperature range of T in the equation (D) is −200 to 1,150° C.

|dA(T)/dT| is preferably 20 ppm/° C. or more, and more preferably 30 ppm/° C. or more at at least one temperature T1 in a range of −200° C. to 1,200° C. The upper limit of |dA(T)/dT| is preferably 1,000 ppm/° C. or less, and more preferably 500 ppm/° C. or less.

The fact that the value of |dA(T)/dT| is 10 ppm/° C. or more at the at least one temperature T1 means that the change in anisotropy of the crystal structure associated with the temperature change is large.

At the at least one temperature T1, dA(T)/dT may be positive or negative, but is preferably negative.

Depending on the type of crystal in the powder, there is a powder whose crystal structure changes due to structural phase transition in a certain temperature range. In the present specification, in a crystal structure at a certain temperature, an axis having the largest crystal lattice constant is defined as a c-axis, and an axis having the smallest crystal lattice constant is defined as an a-axis. In any of the triclinic system, monoclinic system, orthorhombic system, tetragonal system, hexagonal system, and rhombohedral system, the a-axis and the c-axis are defined as described above.

Next, the requirement 2 will be described.

The powder contains at least one metal element or semimetal element, and the at least one metal element or semimetal element is composed of only an element selected from the above-described group. That is, the powder does not contain a metal element or a semimetal element other than the element selected from the group.

The powder is preferably an oxide powder. The oxide powder may be an oxide powder of one type of metal element or semimetal element selected from the above-described group, or may be a so-called composite oxide powder containing a combination of a plurality of elements selected from the group.

The powder is preferably a metal oxide containing at least one metal element in the above-described group. The metal element of the above-described group is Li, Na, Mg, Al, K, Ca, Sc, Ti, V, Cr, Mn, Fe, Co, Ni, Cu, Zn, Ga, Rb, Sr, Y, Zr, Nb, Mo, Tc, Ag, Cd, In, Sn, Cs, Ba, Hf, Ta, W, Re, Au, Hg, Tl, Ce, Pr, Nd, Pm, Sm, Eu, Gd, Tb, Dy, Ho, Er, Tm, Yb, and Lu, excluding Si, Ge, Sb, and Te as semimetal elements from the above-described group.

The powder is preferably a metal oxide containing a metal element having d electrons among the metal elements in the group. The metal element having d electrons is not particularly limited, and examples thereof include a metal element of the fourth period selected from the group consisting of Sc, Ti, V, Cr, Mn, Fe, Co, Ni, and Cu; a metal element of the fifth period selected from the group consisting of Y, Zr, Nb, and Mo; and a metal element of the sixth period selected from the group consisting of Hf, Ta, and W.

Among the above metal elements, the powder is preferably a metal oxide powder containing a metal element of the fourth period or the fifth period, and more preferably a metal oxide powder containing a metal element of the fourth period. The metal element of the fourth period is a metal element having only 3d electrons among d electrons. In particular, from the viewpoint of the occupied state of 3d electrons, the metal oxide powder is preferably a metal oxide powder containing at least one metal element selected from the group consisting of Ti, V, Cr, Mn, and Co among the metal elements of the fourth period. Among them, a metal oxide powder containing titanium is preferable from the viewpoint of the resource.

The metal oxide powder containing titanium is preferably a powder represented by a composition formula TiOₓ (x=1.30 to 1.66), and more preferably a powder represented by a composition formula TiOₓ (x=1.40 to 1.60). In TiOₓ, some of Ti atoms may be substituted with another element.

The metal oxide powder containing titanium may be an oxide powder containing titanium and metal atoms other than titanium, such as LaTiO₃, in addition to the TiOₓ powder.

The crystal structure of the particles constituting the powder is preferably a perovskite structure or a corundum structure, and more preferably a corundum structure.

The crystal system is not particularly limited, but is preferably a rhombohedral system. The space group is preferably attributed to R-3c.

When the powder is a metal oxide powder containing a metal having d electrons, |dA(T)/dT| at −100° C. to 1,000° C. is preferably 10 ppm/° C. or more at at least one temperature.

When the powder is a metal oxide powder containing a metal having only 3d electrons among d electrons, |dA(T)/dT| at −100° C. to 800° C. is preferably 10 ppm/° C. or more at at least one temperature.

When the powder is TiOₓ (x=1.30 to 1.66), |dA(T)/dT| at 0° C. to 500° C. is preferably 10 ppm/° C. or more at at least one temperature.

The particle diameter of the powder is not particularly limited, but D50 in volume-based particle diameter distribution in laser diffraction particle diameter distribution measurement can be about 0.5 to 100 μm.

Next, the requirement 3 will be described. The compact according to the present embodiment is a compact of the above-described powder. The compact in the present embodiment may be a sintered body obtained by sintering a powder.

The compact is usually obtained by sintering the powder satisfying the requirement 1. In this case, it is preferable to perform sintering in a temperature range in which the crystal structure of the powder is maintained.

In order to obtain a sintered body, various known sintering methods can be applied. As a method for obtaining a sintered body, methods such as normal heating, hot pressing, and spark plasma sintering can be employed.

Spark plasma sintering is a method of obtaining a sintered body by applying a pulsed current to a powder while pressurizing and heating the powder.

The plasma sintering is preferably performed under an inert atmosphere such as argon, nitrogen, or vacuum in order to prevent the resulting compound from being deteriorated by contact with air.

The pressure applied in plasma sintering is preferably in a range of more than 0 MPa and 100 MPa or less. The pressure applied in plasma sintering is preferably 10 MPa or more, and more preferably 30 MPa or more.

The heating temperature of the plasma sintering is preferably sufficiently lower than the melting point of the powder.

The compact according to the present embodiment is not limited to the sintered body, and may be, for example, a green compact obtained by pressure molding of a powder.

As described above, the linear thermal expansion coefficient at −200° C. to 1,200° C. of the compact of a powder is negative at at least one temperature T2. The negative value at the temperature T2 may be lower than 0, but is preferably −5 ppm/° C. or less, and more preferably −10 ppm/° C. or less. The negative value has no particular lower limit, but may be, for example, −4,000 ppm/° C. or more. The linear thermal expansion coefficient of the compact is preferably negative at 30 to 200° C.

According to the compact of a powder according to the present embodiment, it is possible to provide a member with reduced thermal expansion and thus extremely reduce the dimensional change of the member when the temperature varies. Therefore, the present invention can be suitably used for various members used in equipment particularly sensitive to a dimensional change due to temperature.

In addition, combining the compact of a powder with another material having a positive linear thermal expansion coefficient allows the linear thermal expansion coefficient of the entire member to be controlled to be low. For example, when the compact of a powder of the present embodiment is used for a part of a rod in the length direction and a member made of a material having a positive linear thermal expansion coefficient is used for the other part of the rod, the linear thermal expansion coefficient of the rod in the length direction can be freely controlled according to the abundance ratio between the two materials. For example, it is also possible to make the thermal expansion of the rod in the length direction substantially zero.

### Second Embodiment: Filler Powder

Next, a filler powder according to a second embodiment of the present invention will be described.

The filler powder according to the present embodiment satisfies the following requirements 1, 2, and 4.

Requirement 1: |dA(T)/dT| of the filler powder satisfies 10 ppm/° C. or more at at least one temperature T1 in a range of −200° C. to 1,200° C.

A is (an a-axis (shorter axis) lattice constant of a crystal in the powder)/(a c-axis (longer axis) lattice constant of a crystal in the powder), and each of the lattice constants is obtained from X-ray diffractometry of the powder.

Requirement 2: the filler powder contains at least one metal element or semimetal element, and the at least one metal element or semimetal element is composed of only an element selected from the group consisting of Li, Na, Mg, Al, Si, K, Ca, Sc, Ti, V, Cr, Mn, Fe, Co, Ni, Cu, Zn, Ga, Ge, Rb, Sr, Y, Zr, Nb, Mo, Tc, Ag, Cd, In, Sn, Sb, Te, Cs, Ba, Hf, Ta, W, Re, Au, Hg, Tl, Ce, Pr, Nd, Pm, Sm, Eu, Gd, Tb, Dy, Ho, Er, Tm, Yb, and Lu.

Requirement 4: a linear thermal expansion coefficient at 25 to 320° C. of a solid composition containing 88 parts by weight of the filler powder and 12 parts by weight of sodium silicate is negative at at least one temperature.

Since the requirements 1 and 2 are the same as those of the first embodiment, detailed description thereof will be omitted.

The requirement 4 means that when a reference solid composition containing a filler powder and sodium silicate at predetermined concentrations is prepared, the linear thermal expansion coefficient of the reference solid composition is negative at at least one temperature. The negative value may be less than 0, but is preferably −3 ppm/° C. or less, and more preferably −10 ppm/° C. or less. The negative value has no particular lower limit, but may be, for example, −300 ppm/° C. or more. The linear thermal expansion coefficient of the reference solid composition is preferably negative at 30 to 200° C.

Specifically, the reference solid composition is preferably produced by the following method.

A mixture of a filler powder and an aqueous sodium silicate solution is prepared. In the mixture, the weight ratio is prepared so that the amount of sodium silicate (solid content) with respect to 88 parts by weight of the filler powder is 12 parts by weight. The amount of water in the mixture is not particularly limited, but is preferably prepared so that the solid content concentration (sodium silicate and filler powder) in the mixture is about 83 wt %.

The resulting mixture is placed in a mold made of polytetrafluoroethylene and cured with the following curing profile.

The temperature is raised to 80° C. in 15 minutes, held at 80° C. for 20 minutes, then raised to 150° C. in 20 minutes, and held at 150° C. for 60 minutes. Further, a treatment of raising the temperature to 320° C., holding the temperature for 10 minutes, and lowering the temperature is performed to obtain a reference solid composition.

The particle diameter of the filler powder is not particularly limited, but D50 in volume-based particle diameter distribution in laser diffraction particle diameter distribution measurement can be about 0.5 to 100 μm.

When the filler powder satisfying the above-described requirements is added to another solid material, a solid composition containing the other solid material (first material) and the filler powder is obtained. When the filler powder is used, the linear thermal expansion coefficient of the solid composition can be greatly reduced as compared with the solid material before addition of the filler.

### [Another Solid Material (First Material)]

The first material is not particularly limited, and examples thereof include resins, alkali metal silicates, ceramics, and metals. The first material may be a binder material which binds the filler powders or a matrix material which holds the powders in a dispersed state.

Examples of the resin include thermoplastic resins and thermosetting resins.

Examples of the thermosetting resin include epoxy resin, oxetane resin, unsaturated polyester resin, alkyd resin, phenol resin (novolac resin, resol resin, etc.), acrylic resin, urethane resin, silicone resin, polyimide resin, and melamine resin.

Examples of the thermoplastic resin include polyolefin (polyethylene, polypropylene, etc.), ABS resin, polyamide (nylon 6, nylon 6,6, etc.), polyamide imide, polyester (polyethylene terephthalate, polyethylene naphthalate), liquid crystalline resin, polyphenylene ether, polyacetal, polycarbonate, polyphenylene sulfide, polyimide, polyetherimide, polyether sulfone, polyketone, polystyrene, and polyetheretherketone.

The first material may contain one type of the resin or two or more types of the resins.

The first material is preferably epoxy resin, polyether sulfone, a liquid crystal polymer, polyimide, polyamide imide, or silicone from the viewpoint of being able to enhance heat resistance.

Examples of the alkali metal silicate include lithium silicate, sodium silicate, and potassium silicate. The first material may contain one type of alkali metal silicate or two or more types of alkali metal silicates. These materials are preferable because they have high heat resistance.

The ceramic is not particularly limited, and examples include ceramics such as alumina, silica (including silicon oxide and silica glass), titania, zirconia, magnesia, ceria, yttria, oxide-based ceramics such as zinc oxide and iron oxide; nitride-based ceramics such as silicon nitride, titanium nitride, and boron nitride; silicon carbide, calcium carbonate, aluminum sulfate, barium sulfate, aluminum hydroxide, potassium titanate, talc, kaolin clay, kaolinite, halloysite, pyrophyllite, montmorillonite, sericite, mica, amesite, bentonite, asbestos, zeolite, calcium silicate, magnesium silicate, diatomaceous earth, and silica sand. The first material may contain one type of ceramic or two or more types of ceramics.

Ceramics are preferable because they can increase heat resistance. A sintered body can be produced by spark plasma sintering or the like.

The metal is not particularly limited, and examples thereof include elementary metals such as aluminum, tantalum, niobium, titanium, molybdenum, iron, nickel, cobalt, chromium, copper, silver, gold, platinum, lead, tin, and tungsten, alloys such as stainless steel (SUS), and mixtures thereof. The first material may contain one type of metal or two or more types of metals. Such a metal is preferable because they can increase heat resistance.

### [Other Components]

The solid composition may contain other components other than the first material and the powder. Examples thereof include a catalyst. The catalyst is not particularly limited, and examples thereof include acidic compounds, alkaline compounds, and organic metallic compounds. As the acidic compound, acids such as hydrochloric acid, sulfuric acid, nitric acid, phosphoric acid, phosphoric acid, formic acid, acetic acid, and oxalic acid can be used. As the alkaline compound, ammonium hydroxide, tetramethylammonium hydroxide, tetraethylammonium hydroxide, or the like can be used. Examples of the organic metallic compound catalyst include those containing aluminum, zirconium, tin, titanium, and zinc.

### [Weight Ratio of Each Component]

The content of the filler powder in the solid composition is usually 3 wt % or more and 95 wt % or less, and preferably 5 wt % or more and 95 wt % or less. With this content, the effect of reducing the linear thermal expansion coefficient appears. The content is more preferably 10 wt % or more, still more preferably 40 wt % or more, and still more preferably 70 wt % or more.

The content of the first material in the solid composition is usually 1 wt % or more and 99 wt % or less, and preferably 5 wt % or more and 95 wt % or less. The content is more preferably 10 wt % or more and 80 wt % or less.

### <Method for Producing Solid Composition>

The method for producing a solid composition is not particularly limited.

For example, a filler powder and a raw material of the first material are mixed to obtain a mixture, and then the raw material of the first material in the mixture is converted into the first material, whereby a solid composition in which the filler powder and the first material are combined can be produced.

For example, when the first material is a resin or an alkali metal silicate, a mixture containing a solvent, a resin or an alkali metal silicate, and a filler powder is prepared, and the solvent is removed from the mixture, whereby a solid composition containing the filler powder and the first material can be obtained. As a method for removing the solvent, a method of evaporating the solvent by natural drying, vacuum drying, heating, or the like can be applied. From the viewpoint of suppressing generation of coarse bubbles, when removing the solvent, the solvent is preferably removed while maintaining the temperature of the mixture at a temperature equal to or lower than the boiling point of the solvent.

When the first material is a resin, the solvent is, for example, an organic solvent such as an alcohol solvent, an ether solvent, a ketone solvent, a glycol solvent, a hydrocarbon solvent, or an aprotic polar solvent, or water. The solvent in the case of the alkali metal silicate is, for example, water.

When the resin is a curable resin, it is preferable to perform a crosslinking treatment of the resin in the mixture after removing the solvent. Specifically, the mixture from which the solvent has been removed may be heated to a temperature equal to or higher than the boiling point of the solvent, or the mixture from which the solvent has been removed may be irradiated with energy rays such as ultraviolet rays. In the case of the alkali metal silicate, a curing treatment may be performed by further heating the mixture after removing the solvent.

When the first material is a ceramic or a metal, a mixture of a raw material powder of the first material and a powder is prepared, and the mixture is heat-treated to sinter the raw material powder of the first material, whereby a solid composition containing the first material and the powder as a sintered body is obtained. The pores of the solid composition can be adjusted as necessary by a heat treatment such as annealing. As the sintering method, methods such as normal heating, hot pressing, and spark plasma sintering can be employed.

When the mixture is applied onto a substrate and then the solvent is removed or sintering is performed, a sheet-like solid composition can be obtained. In addition, when the mixture is supplied to a mold and then the solvent is removed or sintering is performed, a solid composition having an optional shape corresponding to the shape of the mold can be obtained.

Furthermore, the size and distribution of pores can be adjusted by a heat treatment of the resulting solid composition.

Subsequently, a specific use form of the compact of a powder and the solid composition containing a powder filler will be described.

The compact of a powder and the solid composition containing a powder filler according to the embodiment can be a mechanical member, a container, an optical member, a member for electronic devices, or an adhesive.

### [Mechanical Member]

The mechanical member is a member constituting various types of mechanical equipment. Examples of the mechanical equipment include machine tools such as cutting equipment, processing devices, and semiconductor manufacturing equipment. Examples of the mechanical member include a fixing mechanism, a moving mechanism, and a tool. According to the heat dissipation member using the compact of a powder and the solid composition, dimensional deviation due to thermal expansion can be suppressed, thus enabling improvement in accuracy such as machining accuracy and processing accuracy. In addition, the compact of a powder and the solid composition are suitable for use in a joint portion between members made of different materials.

The mechanical member may be a rotating member. The rotating member refers to a member that exerts a mechanical action on another member while rotating, such as a gear. When the dimension of the rotating member changes due to thermal expansion, problems such as poor engaging and abrasion occur. Thus, the compact of a powder and the solid composition of the present embodiment are suitable for application to the rotating member.

The mechanical member may be a substrate. When the dimension of the substrate changes due to thermal expansion, a problem such as misalignment occurs. Thus, the compact of a powder and the solid composition of the present embodiment are suitable for application to the substrate.

### [Container]

The container is a member for accommodating gas, liquid, solid, or the like. For example, an example of the container is a mold for producing a compact. For example, when the dimension of the mold changes due to thermal expansion, a problem occurs that the dimensional accuracy of the compact cannot be maintained. Thus, the compact of a powder and the solid composition of the present embodiment are suitable for application to the mold.

### [Optical Member]

Examples of the optical member include an optical fiber, an optical waveguide, a lens, a reflecting mirror, a prism, an optical filter, a diffraction grating, a fiber grating, and a wavelength conversion member. Examples of the lens include an optical pickup lens and a camera lens. Examples of the optical waveguide include an array waveguide and a planar optical circuit.

The optical member has a problem that the characteristics thereof vary when the lattice spacing, the refractive index, the optical path length, or the like changes with a change in temperature. According to the optical member, or the fixing member or supporting substrate of the optical member using the compact of a powder and the solid composition, it is possible to reduce such variation in characteristics of the optical member depending on the temperature.

### [Member for Electronic Devices]

Examples of the member for electronic devices include a sealing member, a circuit board, a prepreg, a film-like adhesive, a conductive paste, an anisotropic conductive film, and an insulating sheet.

Examples of the sealing member include a sealing member of a semiconductor element, an underfill member, and an interchip fill for a 3D-LSi. Examples of the semiconductor element include a power semiconductor such as a power transistor and a power IC; and a light emitting element such as an LED element. According to the sealing member of the semiconductor using the compact of a powder and the solid composition, it is possible to suppress cracking due to a difference in linear thermal expansion coefficient.

The circuit board includes a metal layer and an electrically insulating layer provided on the metal layer. Use of the compact of a powder and the solid composition for the electrically insulating layer can reduce the linear thermal expansion coefficient of the electrically insulating layer to thereby reduce the difference in the linear thermal expansion coefficient between the electrically insulating layer and the metal layer, and thus can eliminates problems such as warpage and cracking. Specific examples of the circuit board include a printed circuit board, a multilayer printed wiring board, a build-up board, and a capacitor built-in board.

The prepreg is a semi-cured product of an impregnated material containing a reinforcing material and a matrix material impregnated into the reinforcing material. Inclusion of the filler powder of the present embodiment in the prepreg allows the cured prepreg to exhibit dimensional stability even under a thermal load.

Examples of the film-like adhesive include a die-bonding film, and examples of the conductive paste include a resin paste for circuit connection and an anisotropic conductive paste. Inclusion of the filler powder of the present embodiment in the film-like adhesive, the conductive paste, and the anisotropic conductive film can reduce the linear thermal expansion of the adhesive member. This can eliminate problems such as cracking and warpage in the contact portion between different materials.

An example of the insulating sheet is a resin sheet such as a sheet made of polyvinyl chloride. When the filler powder is added to the insulating sheet, the dimensional accuracy thereof can be improved.

### [Adhesive]

Examples of the adhesive include an adhesive containing a thermosetting resin such as epoxy or silicone resin as a matrix material and the filler powder. The adhesive can be liquid before curing. Since the cured product of the adhesive can have a low linear thermal expansion coefficient, cracking can be suppressed. In particular, the adhesive is suitable for application to a heat-resistant adhesive member to which a thermal load is applied.

### EXAMPLES

Hereinafter, the present invention will be described in more detail with reference to Examples.

### 1. Crystal Structure Analysis of Powder

As the analysis of the crystal structure, a powder was subjected to powder X-ray diffractometry at different temperatures under the following conditions using a powder X-ray diffractometer SmartLab (manufactured by Rigaku Corporation) to obtain a powder X-ray diffraction pattern. The lattice constant was refined based on the obtained pattern by the least-squares method using PDXL2 software (manufactured by Rigaku Corporation), and two lattice constants, that is, the a-axis length and the c-axis length were obtained.

Measuring apparatus: powder X-ray diffractometer SmartLab (manufactured by Rigaku Corporation) X-ray generator: CuKα radiation source voltage 45 kV, current 200 mA

Slit: slit width 2 mm

Scan step: 0.02 deg

Scan range: 5 to 80 deg

Scan speed: 10 deg/min

X-ray detector: one-dimensional semiconductor detector

Measurement atmosphere: Ar 100 mL/min

Sample stage: dedicated glass substrate made of SiO₂

### 2. Measurement of Linear Thermal Expansion Coefficient of Reference Solid Composition and Compact

Measuring apparatus: Thermo plus EVO2, TMA series, Thermo plus 8:310

Reference: alumina

The temperature range was set to 25° C. to 320° C., and the value of the linear thermal expansion coefficient at 190 to 210° C. was calculated as a representative value.

The typical size of the solid composition was 15 mm×4 mm×4 mm.

The sample length L(T) at the temperature T was measured assuming that the longest side of the solid composition with a size of 15 mm×4 mm×4 mm was defined as the sample length L. The dimensional change rate ΔL(T)/L (30° C.) with respect to the sample length at 30° C. (L(30° C.)) was calculated by the following equation.

ΔL(T)/L(30° C.)=(L(T)−L(30° C.))/L(30° C.)

In the present specification, the linear thermal expansion coefficient α at the temperature T is defined as follows.

α(l/° C.)=(ΔL(T+20° C.)−ΔL(T))/(L(30° C.)×20° C.)

in the present example, T is 190° C., the dimensional change rate ΔL(T)/L(30° C.) was obtained at each temperature of 190° C. and 210° C., and the linear thermal expansion coefficient α(l/° C.) at a temperature T of 190° C., in other words, the linear thermal expansion coefficient α (1/° C.) at 190° C. to 210° C. was calculated by the following equation.

α(1/° C.)=(ΔL(210° C.)−ΔL(190° C.))/(L(30° C.)×20° C.)

### EXAMPLES

The filler powders and the reference solid compositions of Examples 1 and 2 and Comparative Example 1, and the compact of a powder of Example 3 were obtained by the following method.

### Example 1

A Ti₂O₃ powder (150 μm Pass, purity 99.9%, manufactured by Kojundo Chemical Laboratory Co., Ltd.) was prepared as a filler powder.

Then, 80 parts by weight of each filler powder, 20 parts by weight of sodium silicate No. 1 (aqueous sodium silicate solution) manufactured by Fuji Chemical Co., Ltd., and 10 parts by weight of pure water were mixed to obtain a mixture. The solid content in sodium silicate No. 1 manufactured by Fuji Chemical Co., Ltd. was about 55 wt %.

The resulting mixture was placed in a mold made of polytetrafluoroethylene and cured with the following curing profile.

The temperature was raised to 80° C. in 15 minutes, held at 80° C. for 20 minutes, then raised to 150° C. in 20 minutes, and held at 150° C. for 60 minutes. Thereafter, a treatment of raising the temperature to 320° C., holding the temperature for 10 minutes, and lowering the temperature was performed to obtain a reference solid composition through the above steps.

### Example 2

The Ti₂O₃ powder (150 μm Pass, purity 99.9%, manufactured by Kojundo Chemical Laboratory Co., Ltd.) of Example 1 was pulverized by a bead mill under the following conditions to obtain a filler powder used in Example 2.

Pulverization conditions: a batch-type ready mill (RM B-08) manufactured by AIMEX Co., Ltd. was used as the bead mill. Pulverization was performed using a 800 cm³ vessel under conditions of 1,348 rpm and a peripheral speed of 5 m/s. ZrO₂ beads having a particle diameter of 1 mm were used, 217 g of water, 613 g of ZrO₂, and Ti₂O₃ (150 μm Pass, 24.9 g, manufactured by Kojundo Chemical Laboratory Co., Ltd.) were mixed, and pulverization was performed for 10 minutes.

A reference solid composition was obtained in the same manner as in Example 1 except for using the above filler powder.

### Example 3

A Ti₂O₃ powder (manufactured by Furuuchi Chemical Corporation, 300 mesh, purity 99.9%) was prepared as a powder and subjected to spark plasma sintering to obtain a compact (sintered body) of Example 3.

For spark plasma sintering, a spark plasma sintering apparatus, Doctor Sinter Lab SPS-511S (manufactured by Fuji Electronic Industrial Co., Ltd.) was used. The Ti₂O₃ powder was filled in a dedicated carbon die, and spark plasma sintering was performed under the following conditions.

Apparatus: Doctor Sinter Lab SPS-511S (manufactured by Fuji Electronic Industrial Co., Ltd.)

Sample: Ti₂O₃ powder (manufactured by Furuuchi Chemical Corporation, 300 mesh, purity 99.9%) 5.6 g

Die: dedicated carbon die with an inner diameter of 20 mmφ

Atmosphere: argon 0.05 MPa

Pressure: 40 MPa (3.1 kN)

Heating: 1,250° C. for 10 minutes

### Comparative Example 1

An Al₂O₃ powder (AKP-15 manufactured by Sumitomo Chemical Co., Ltd.) was prepared as a filler powder. A reference solid composition was obtained in the same manner as in Example 1 except for using this filler powder.

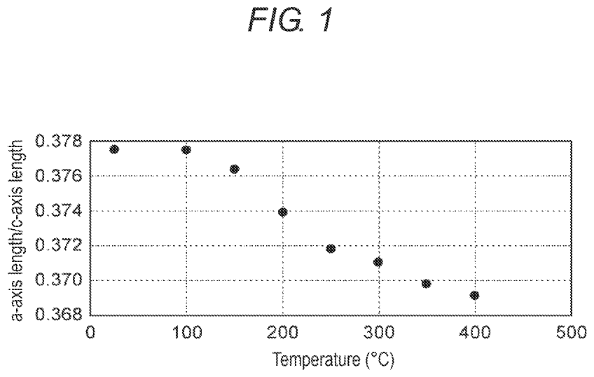

The filler powder of Example 1 was subjected to X-ray diffractometry at 25° C., 100° C., 150° C., 200° C., 250° C., 300° C., 350° C., and 400° C. As a result, the filler powders of Examples 1 and 2 and the powder of Example 3 were attributed to Ti₂O₃ having a corundum structure, and the space group was R-3c. The a-axis length, the c-axis length, and the a-axis length/c-axis length of the filler powder of Example 1 at each of the above temperatures are summarized in Table 1. The relationship between the a-axis length/c-axis length and the temperature T in the filler powder of Example 1, that is, A(T) is shown in FIG. 1. In the filler powder of Example 1, dA(T)/dT=(A (T+50)−A (T))/50 was −49 ppm/° C., and |dA(T)/dT| was 49 ppm/° C. at a temperature T1 of 150° C.

The filler powder of Example 2 was subjected to X-ray diffractometry at 150° C. and 200. As a result, the filler powder of Example 2 was attributed to Ti₂O₃ having a corundum structure, and the space group was R-3c. At a temperature T of 150° C., dA(T)/dT=(A (T+50)−A(T))/50 was −44 ppm/° C. In addition, at a temperature T of 150° C., |dA(T)/dT| was 44 ppm/° C.

The powder of Example 3 was subjected to X-ray diffractometry at 150° C. and 200. As a result, the powder of Example 3 was attributed to Ti₂O₃ having a corundum structure, and the space group was R-3c. At a temperature T of 150° C., dA(T)/dT=(A(T+50)−A(T))/50 was −49 ppm/° C. In addition, at a temperature T of 150° C., |dA(T)/dT| was 49 ppm/° C.

TABLE 1

| | | | a-axis length/ |
|---|---|---|---|
| Temperature | a-axis length | c-axis length | c-axis length |
| (° C.) | (Å) | (Å) | (—) |
| 25 | 5.151 | 13.645 | 0.378 |
| 100 | 5.151 | 13.647 | 0.377 |
| 150 | 5.148 | 13.677 | 0.376 |
| 200 | 5.137 | 13.737 | 0.374 |
| 250 | 5.132 | 13.802 | 0.372 |
| 300 | 5.127 | 13.816 | 0.371 |
| 350 | 5.125 | 13.857 | 0.370 |
| 400 | 5.123 | 13.877 | 0.369 |

The linear thermal expansion coefficients of the reference solid compositions of Examples 1 and 2 and Comparative Example 1 and the compact of Example 3 at a temperature T of 190° C., that is, 190 to 210° C. were −38.0 ppm/° C., −3.6 ppm/° C., −55.5 ppm/° C., and 7.9 ppm/° C. in the order of Example 1, Example 2, Example 3, and Comparative Example 1. The results are shown in Table 2.

In Comparative Example 1, the linear thermal expansion coefficients α were all positive within a temperature range of 25 to 320° C.

TABLE 2

| | | Linear thermal expansion |
|---|---|---|
| | | coefficient at 190° C. |
| | \|dA(T)/dT\| | to 210° C. of reference |
| | at 150° C. | solid composition or compact |
| | (ppm/° C.) | (ppm/° C.) |
| Example 1 | 49 | −38.0 |
| Example 2 | 49 | −3.6 |
| Example 3 | 49 | −55.5 |
| Comparative Example 1 | 49 | 7.9 |

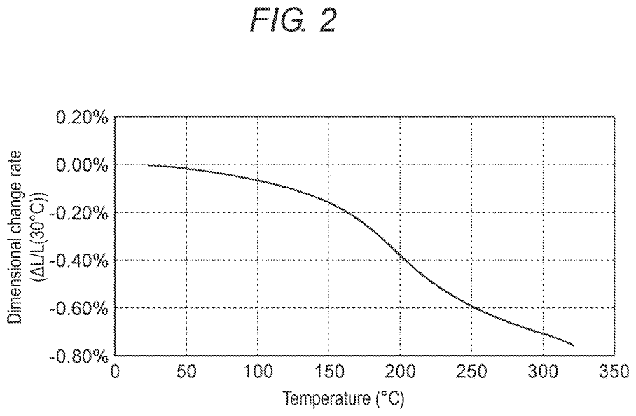

The temperature dependency of the dimensional change rate ΔL(T)/L(30° C.) of the compact of Example 3 is shown in FIG. 2.

The slope of the dimensional change rate corresponds to the linear thermal expansion coefficient.

The filler powder and the compact according to the embodiment can provide a solid composition having a low linear thermal expansion coefficient.

1. A compact of a powder satisfying the following requirements 1 to 3:
requirement 1: |dA(T)/dT| of the powder satisfies 10 ppm/° C. or more at at least one temperature T1 in a range of −200° C. to 1,200° C.
where A is (an a-axis (shorter axis) lattice constant of a crystal in the powder)/(a c-axis (longer axis) lattice constant of a crystal in the powder), and each of the lattice constants is obtained from X-ray diffractometry of the powder;
requirement 2: the powder contains at least one metal element or semimetal element, and the at least one metal element or semimetal element is composed of only an element selected from the group consisting of Li, Na, Mg, Al, Si, K, Ca, Sc, Ti, V, Cr, Mn, Fe, Co, Ni, Cu, Zn, Ga, Ge, Rb, Sr, Y, Zr, Nb, Mo, Tc, Ag, Cd, In, Sn, Sb, Te, Cs, Ba, Hf, Ta, W, Re, Au, Hg, Tl, Ce, Pr, Nd, Pm, Sm, Eu, Gd, Tb, Dy, Ho, Er, Tm, Yb, and Lu: and
requirement 3: a linear thermal expansion coefficient at −200° C. to 1,200° C. of the compact is negative at at least one temperature.

2. The compact according to claim 1, wherein the powder is a metal oxide powder.

3. The compact according to claim 2, wherein the metal oxide powder contains a metal having d electrons.

4. The compact according to claim 2, wherein the metal oxide powder is a metal oxide powder containing titanium.

5. The compact according to claim 4, wherein the metal oxide powder containing titanium is a TiOₓ (x=1.30 to 1.66) powder.

6. The compact according to claim 1, wherein the compact is a heat dissipation member, a mechanical member, a container, an optical member, a member for electronic devices, or an adhesive.

7. A filler powder satisfying the following requirements 1, 2, and 4:
requirement 1: |dA(T)/dT| of the filler powder satisfies 10 ppm/° C. or more at at least one temperature T1 in a range of −200° C. to 1,200° C.
where A is (an a-axis (shorter axis) lattice constant of a crystal in the powder)/(a c-axis (longer axis) lattice constant of a crystal in the powder), and each of the lattice constants is obtained from X-ray diffractometry of the powder;
requirement 2: the filler powder contains at least one metal element or semimetal element, and the at least one metal element or semimetal element is composed of only an element selected from the group consisting of Li, Na, Mg, Al, Si, K, Ca, Sc, Ti, V, Cr, Mn, Fe, Co, Ni, Cu, Zn, Ga, Ge, Rb, Sr, Y, Zr, Nb, Mo, Tc, Ag, Cd, In, Sn, Sb, Te, Cs, Ba, Hf, Ta, W, Re, Au, Hg, Tl, Ce, Pr, Nd, Pm, Sm, Eu, Gd, Tb, Dy, Ho, Er, Tm, Yb, and Lu; and
requirement 4: a linear thermal expansion coefficient at 25 to 320° C. of a solid composition containing 88 parts by weight of the filler powder and 12 parts by weight of sodium silicate is negative at at least one temperature.

8. The filler powder according to claim 7, wherein the filler powder is a metal oxide powder.

9. The filler powder according to claim 8, wherein the metal oxide powder is a metal oxide powder having d electrons.

10. The filler powder according to claim 8, wherein the metal oxide powder is a metal oxide powder containing titanium.

11. The filler powder according to claim 10, wherein the metal oxide powder containing titanium is a TiOₓ (x=1.30 to 1.66) powder.
